(19) United States
(12) Patent Application Publication
(10) Pub. No.: US 2007/0246737 A1
(43) Pub. Date: Oct. 25, 2007

(54) Electrostatic discharge protection apparatus for integrated circuits

(76) Inventor: Hung-Yi Chang, Hsinchu City (TW)

Correspondence Address: J.C. Patents, Inc., Suite 250, 4 Venture, Irvine, CA, 92618, US

(21) Appl. No.: 11/408,684

(22) Filed: Apr. 20, 2006

(51) Int. Cl. H01L 29/74

(52) U.S. Cl. 257/107

(57) ABSTRACT

An electrostatic discharge (ESD) protection apparatus for integrated circuits is provided. The ESD protection apparatus includes an ESD protection device. The ESD protection device is disposed in a guard ring and includes a special ESD protection unit and an ESD protection unit. The special ESD protection unit is parallel to the ESD protection unit and is disposed on the edge of the ESD protection device. The special ESD protection unit includes at least a special channel area and a plurality of contact windows. The minimum spacing between the two contact windows at two sides of the special channel area in the special ESD protection unit is greater than the minimum spacing between the two contact windows at two sides of the channel area in the ESD protection unit.

### BACKGROUND OF THE INVENTION

1. Field of Invention

The present invention relates to an electrostatic discharge (ESD) protection apparatus. More particularly, the present invention relates to an ESD protection apparatus which uses different channel widths and layouts to improve the ESD protection capability thereof.

2. Description of Related Art

Since the deep-submicron technology is applied in integrated circuits (IC), the capability of enduring electrostatic discharge of the ICs is reduced along with the reduced size of the devices. Thus, the capability requirement of the ESD protection to the ICs, to prevent the ESD from damaging the ICs, is higher. In particular, the input/output of ICs need the most protection of ESD protection apparatus since they are most vulnerable to the damage caused by ESD.

The structure of a conventional ESD protection apparatus usually comprises transistors of finger structure, which include P channel metal oxide semiconductor (PMOS) transistors and N channel metal oxide semiconductor (NMOS) transistors, for preventing the electrostatic current from damaging the IC. Generally speaking, finger structures are all symmetrical structures, and the distances between the contact windows connecting solder pads and the channel areas (the ploy area in the layout, i.e. the gate) are also the same. However, the relative distance between each finger structure and solder pad is different, and the distance between each finger structure and the ground terminal is also different, thus the parasitic resistance is different. Accordingly, when ESD occurs, some finger structures would break down or be damaged by the electrostatic current ahead of time because the electrostatic current carried by each finger structure is different, which would make the ESD protection apparatus ineffective,

U.S. Pat. No. US6,815,775B2 discloses a typical ESD protection apparatus for resolving the problem of ESD. The layout of the ESD protection device thereof is illustrated in FIG. 1. As shown in FIG. 1, the widths of the channel areas 115 in the finger structures are all the same. In each finger structure, the distance between the contact window 110 thereof and the channel area 115 thereof is always the same. However, if different channel widths are required in the actual design to achieve different current driving capabilities, the transistor having different channel widths may become the soft spot of the ESD protection device.

### SUMMARY OF THE INVENTION

Accordingly, the present invention is directed to provide an electrostatic discharge (ESD) protection apparatus, which is applicable to circuits of different current driving capabilities, by disposing special ESD protection devices of different channel widths in the finger structures. In addition, the ESD protection capability is improved by disposing special ESD protection units of different channel widths and the guard ring at different relative positions and increasing the spacing between the contact windows and the channel areas in the special ESD protection units.

The present invention provides an ESD protection apparatus including a substrate, an ESD protection device, and a guard ring. Wherein, the ESD protection device is disposed in the guard ring and includes at least one ESD protection unit, a special ESD protection unit, and a plurality of contact windows. The substrate has a substrate doped region and the substrate doped region is formed as the base of the ESD protection device. The special ESD protection unit is parallel to the ESD protection unit, and the special ESD protection unit is disposed on the edge of the ESD protection device; that is, close to the guard ring. The parasitic resistance between the base and the guard ring is small because the spacing inbetween is small, thus it can not be easily turned on when ESD occurs, so that the special ESD protection unit is prevented from damage due to the electrostatic current.

The foregoing ESD protection unit includes a first doped region, a second doped region, and a channel area, wherein the channel area is located between the first doped region and the second doped region. A plurality of contact windows are respectively disposed in the first doped region and the second doped region at two sides of the channel. The special ESD protection unit includes a first doped region, at least one second doped region, and a corresponding special channel area. A plurality of contact windows are respectively disposed at two sides of the special ESD protection unit, i.e. in the first doped region and the second doped region of the special ESD protection unit.

Wherein, the channel width of the special channel area in the special ESD protection unit is smaller than the channel widths of the channel areas in other ESD protection units, and the minimum spacing between the contact windows at two sides of the special channel area in the special ESD protection unit is greater than the minimum spacing between the contact windows at two sides of the channel area in the ESD protection unit. Based on the difference in the spacing and by reducing the parasitic resistance at the base of the special ESD protection unit, the special ESD protection unit cannot be easily turned on so that the special ESD protection unit of smaller channel width is prevented from damage due to transient electrostatic current.

The main structures in the ESD protection devices are all the same. There are different doped regions at two sides of the channel areas thereof, and the substrate doped regions under the channel areas form the bases of various ESD protection units. Different transistor structures, e.g. NMOS transistor or PMOS transistor, can be formed by using different dopant, e.g. N-type dopant or P-type dopant, at two sides of the channel areas and in the substrate doped regions to be used for ESD protection of different circuit requirements.

Through the design of different channel widths, the ESD protection apparatus of the present invention is applicable to ICs of different current driving capabilities. The design of large spacing between the contact windows and the channel areas and the reduced parasitic resistance at the base can prevent some ESD protection units from damage due to electrostatic current ahead of time that may stop the ESD protection apparatus from protecting the internal IC.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram illustrating the layout of a NMOS ESD protection device disclosed in the U.S. Pat. No. 6,815,775B2.

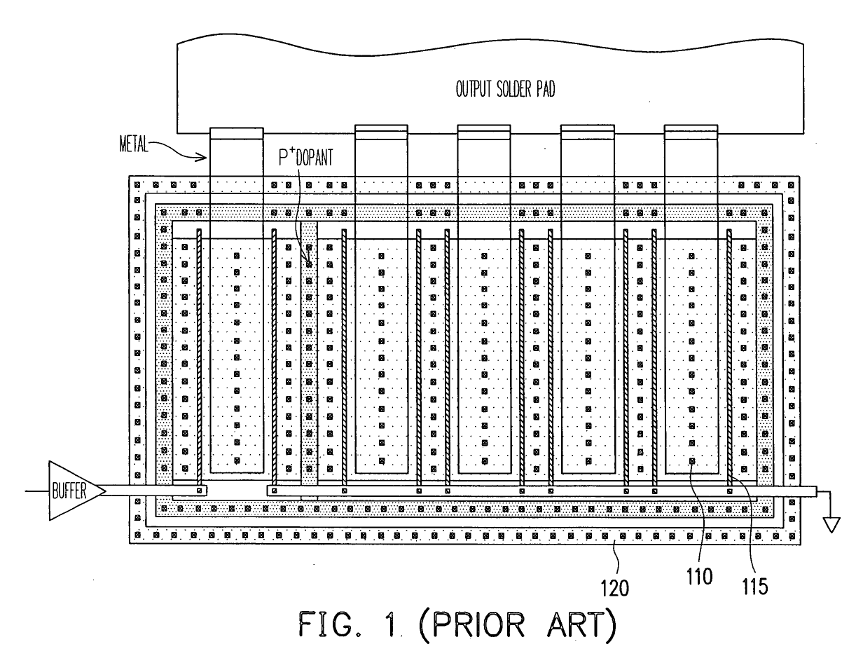

FIG. 2 is a circuit diagram of an ESD protection apparatus according to an embodiment of the present invention.

FIG. 3 is a diagram illustrating the circuit layout of an ESD protection apparatus according to an embodiment of the present invention.

FIG. 4 is a cross-sectional view of a NMOS transistor ESD protection apparatus according to an embodiment of the present invention.

FIG. 5 is a diagram illustrating an equivalent circuit of an ESD protection apparatus according to an embodiment of the present invention.

### DESCRIPTION OF EMBODIMENTS

Reference will now be made in detail to the present embodiment of the present invention, examples of which are illustrated in the accompanying drawings, wherein like reference numerals refer to the like elements throughout.

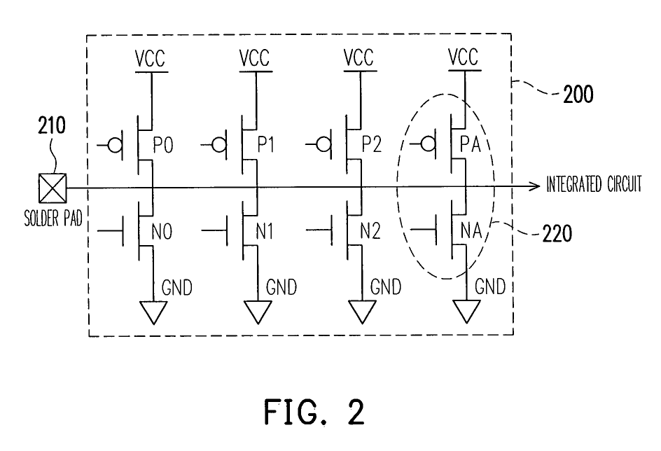

Please refer the following description to FIG. 2, which is a circuit diagram of an ESD protection apparatus according to an embodiment of the present invention. The circuit as shown in FIG. 2 is applicable to ESD protection of integrated circuits (IC). Wherein, PMOS transistors P0˜PA are coupled in parallel between the power supply VCC and the solder pad 210. NMOS transistors N0˜NA are coupled in parallel between the solder pad 210 and the ground GND. The gates of the foregoing transistors P0˜PA and N0˜NA are respectively coupled to control circuits. When ESD occurs at the solder pad 210, the transistors P0˜PA and N0˜NA provide current transmission path according to the mode of the ESD occurrence (e.g. body mode, mechanical mode, device charge mode) and the polarity of the ESD (positive or negative) to prevent the electrostatic current from damaging the internal IC or device connected to the solder pad 210.

To be adapted to ICs of different driving capabilities, the special ESD protection unit 220 has to be integrated into the ESD protection circuit 200. The channel widths of the transistors PA and NA included in the special ESD protection unit 220 are different from the channel widths of the other transistors P0˜P2 and N0˜N2, so that the ESD protection circuit 200 can be adjusted according to ICs of different driving capabilities. In the circuit layout of the ESD protection circuit 200, PMOS transistors P0˜PA and NMOS transistors N0˜NA are usually located adjacently. The structure thereof includes finger circuit layout, with the finger structure. A doped region is shared by two adjacent transistors as the common source/drain, so as to reduce the chip area and improve the ESD protection capability of the ESD protection circuit 200. Moreover, FIG. 2 is a circuit diagram of an ESD protection apparatus according to an embodiment of the present invention, while the number of transistors shown in FIG. 2 is not to limit the number of transistors used in the circuit of the present invention.

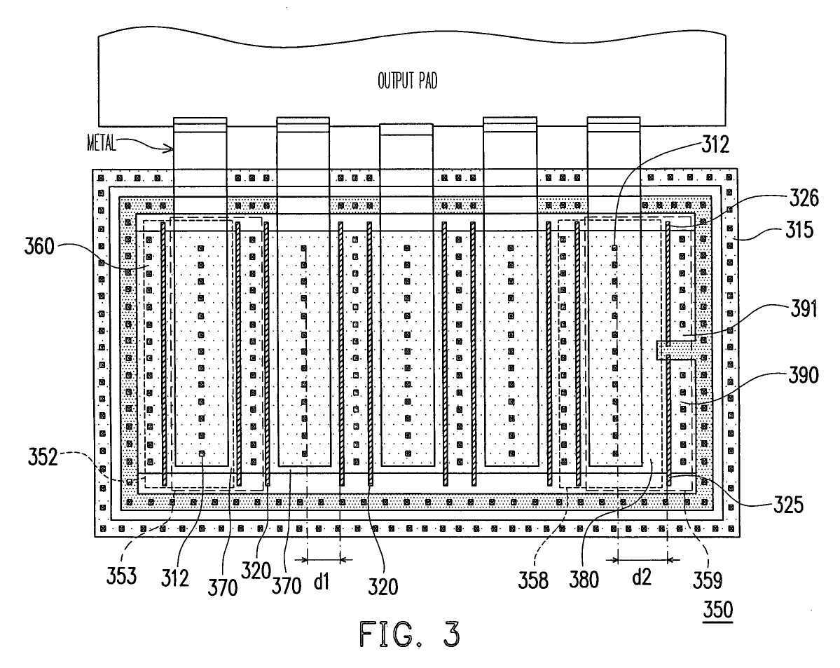

FIG. 3 is a diagram illustrating the circuit layout of an ESD protection apparatus according to an embodiment of the present invention.

Next, the structure of using different channel widths and the layout thereof will be further described in the present embodiment with reference to the structure and layout of the NMOS transistor ESD protection device 350. The impact on the ESD protection apparatus due to the difference in parasitic resistance is reduced through the layout thereof. The NMOS transistor ESD protection device 350 includes a plurality of ESD protection units 352 and a special ESD protection unit 359. Each ESD protection unit 352 includes a doped region 370, a doped region 360, and a channel area 320, and the channel area 320 is disposed between the doped region 370 and the doped region 360. The channel area 320, the doped region 370, and the doped region 360 respectively form the gate, the first source/drain, and the second source/drain of a NMOS transistor.

As shown in FIG. 3, similarly, the ESD protection unit 358 adjacent to the special ESD protection unit 359 includes a channel area 320, a doped region 370, and a doped region 360. Wherein, the doped region 370 included in the ESD protection unit 358 overlaps the doped region 380 included in the special ESD protection unit 359. They are virtually the same region shared by the ESD protection unit 358 and the special ESD protection unit 359. The special ESD protection unit 359 is parallel to the ESD protection units and is disposed on the edge of the NMOS transistor ESD protection device; that is, the special ESD protection unit 359 is disposed close to the guard ring 315, so that the parasitic resistance between the base thereof and the guard ring 315 is small. This small parasitic resistance makes the special ESD protection unit 359 harder to be turned on, so that the special ESD protection unit 359 is protected from damages due to electrostatic current.

The foregoing special ESD protection unit 359 includes a doped region 380, at least one special channel area 325, and a corresponding doped region 390. Wherein, each special channel area 325 is disposed between the doped region 380 and the corresponding doped region 390. In the present embodiment, the special ESD protection unit 359 includes two special channel areas 325 and two corresponding doped regions 390. Moreover, the widths of the special channel areas 325 are smaller than the width of the channel area 325. The adoption of the combination of different channel area widths allows the output buffers of ICs having different driving capabilities.

As shown in FIG. 3, another special channel area 326 and the corresponding doped region 391 are respectively disposed above the special channel area 326 and the doped region 390.

In addition, the spacing between the contact windows 312 and the special channel areas 325 and 326 in the special ESD protection unit 359 are increased. In other words, the spacing d2 between the contact windows 312 located in the doped region 380 and the special channel areas 325 and 326 is larger than the spacing d1 between the contact windows 312 located in the doped region 370 and the adjacent channel areas 320. This difference in spacing will affect the parasitic resistance between the contact windows and the transistor channel areas. The larger the spacing, the higher the resistance. Accordingly, the transistor having the special channel areas 325 and 326 has higher parasitic resistance at the first source/drain thereof, which can prevent electrostatic current from passing through the special channel areas 325 and 326 and causing damage.

The method of forming transistors of different channel widths with special channel areas in the NMOS transistor ESD protection device 350 in the present embodiment can also be applied to the PMOS transistor ESD protection device, and the implementation method thereof should be known to those with ordinary skill in the art based on the disclosure of the present invention, so will not be described.

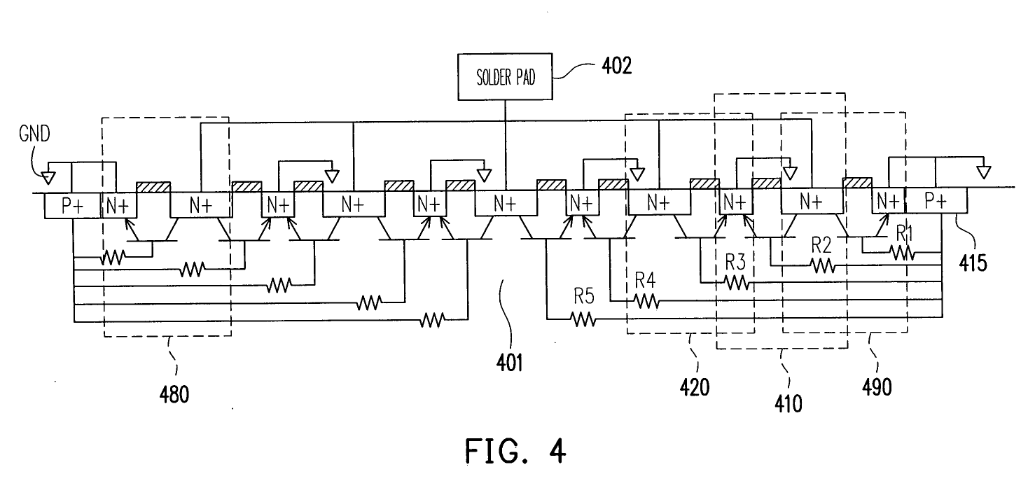

FIG. 4 is a cross-sectional view of an NMOS transistor ESD protection apparatus according to an embodiment of the present invention. The NMOS transistor 490 having a special channel area is disposed on the edge of the ESD protection apparatus. The NMOS transistor 490 is closer to the guard ring doped region 415 than the parallel NMOS transistors 410 and 420, thus the parasitic resistance R1 at the base of the NMOS transistor 490 is smaller than the other parasitic resistances R2˜R5. The NMOS transistor 490 is the special ESD protection unit shown in FIG. 3, while the NMOS transistors 410˜480 are respectively ESD protection units referred to thereinafter as transistors 410˜490. Instead, a plurality of transistors having special channel areas can be disposed according to the actual requirement.

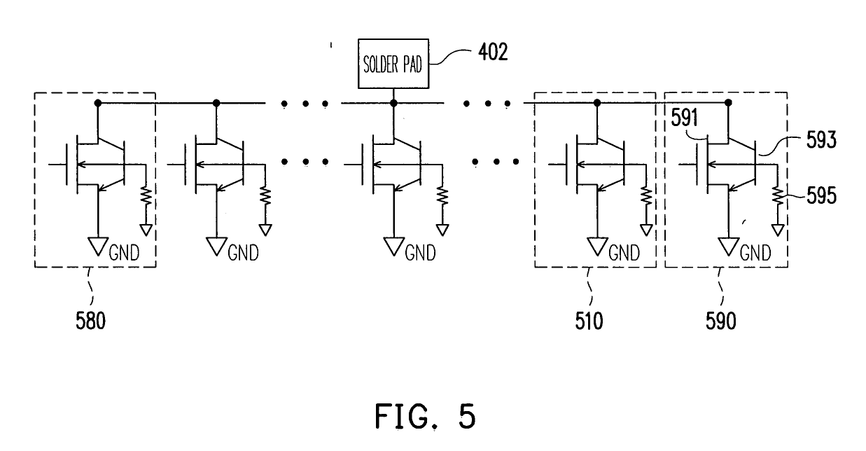

FIG. 5 is a diagram illustrating an equivalent circuit of an ESD protection apparatus according to an embodiment of the present invention. The special ESD protection unit 590 and the ESD protection units 510˜580 are coupled in parallel between the solder pad 402 and the ground GND. The circuit structure of the special ESD protection unit 590 is an NMOS transistor 591 and a parasitic bipolar transistor 593 coupled in parallel between the solder pad 402 and the ground GND.

In addition, the channel width of the special ESD protection unit 590 is smaller than the channel widths of the NMOS transistors 510˜580. The base parasitic resistor 595 is coupled between the foregoing common base and the ground GND. When ESD occurs on the solder pad 402, the electrostatic current can be led to ground through the NMOS transistor and the parasitic bipolar transistor in a particular ESD protection unit, so as to prevent the electrostatic current from damaging the IC coupled to the solder pad. Even though only one special ESD protection unit is disposed in the present embodiment, the number of special ESD protection units can be changed in the equivalent circuit diagram of the actual application according to the actual requirement.

In another embodiment of the present invention, the layout method of the present invention can be applied to the ESD protection apparatus of PMOS transistors, and the similar protection result is achieved. The implementation method for PMOS transistors shall be conceived by those skilled in the art base on the disclosure of the present invention, which shall not be further described.

In overview, according to the layout of the present invention, the special ESD protection unit having shorter channel width is disposed closer to the guard ring to reduce the base parasitic resistance and, at the same time, increase the spacing between the contact windows and the special channel area, so that the parasitic resistance between the source/drain and the channel area is increased. With the aforementioned two layouts, the ESD protection apparatus can be applied to ICs of different driving capabilities through adjustment. Meanwhile, damages to particular devices can be prevented when ESD occurs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electrostatic discharge (ESD) protection apparatus applicable to the ESD protection of integrated circuits (IC), the apparatus comprising:
a substrate, having a substrate doped region, forming a base of the ESD protection apparatus; and
an ESD protection device, disposed in the substrate doped region, located in a guard ring, the ESD protection device comprising:
at least one ESD protection unit, wherein each ESD protection unit has a channel area;
a special ESD protection unit, parallel to the ESD protection unit, located on the edge of the ESD protection device, including at least one special channel area; and
a plurality of contact windows, respectively disposed at two sides of the channel area and the special channel area,
wherein, the minimum spacing between the contact windows at two sides of the special channel area in the special ESD protection unit is greater than the minimum spacing between the contact windows at two sides of the channel area in the ESD protection unit.

2. The ESD protection apparatus as claimed in claim 1, wherein the ESD protection unit further comprises:
a first doped region; and
a second doped region, the channel area being disposed between the first doped region and the second doped region.

3. The ESD protection apparatus as claimed in claim 2, wherein the first doped region and the second doped region include an N-type dopant.

4. The ESD protection apparatus as claimed in claim 2, wherein the first doped region and the second doped region include a P-type dopant.

5. The ESD protection apparatus as claimed in claim 1, wherein the special ESD protection device further comprises:
a first doped region; and
at least one second doped region, the corresponding special channel area being disposed between the first doped region and the corresponding second doped region.

6. The ESD protection apparatus as claimed in claim 5, wherein the first doped region and thesecond doped region include an N-type dopant.

7. The ESD protection apparatus as claimed in claim 5, wherein the first doped region and the second doped region include a P-type dopant.

8. The ESD protection apparatus as claimed in claim 1, wherein the substrate doped region includes an N-type dopant.

9. The ESD protection apparatus as claimed in claim 1, wherein the substrate doped region includes a P-type region.

10. The ESD protection apparatus as claimed in claim 1, wherein the width of the special channel area is smaller than the width of the channel area.
